(19) United States
(12) Patent Application Publication
(10) Pub. No.: US 2002/0148625 A1
(43) Pub. Date: Oct. 17, 2002

(54) Shielding device for a hand-held radiophone

(76) Inventors: Keld Emlington Darling, Herlev (DK); Flemming Wedel, Kastrup (DK); Henrik Madsen, Copenhagen NV (DK)

Correspondence Address: BIRCH STEWART KOLASCH & BIRCH, PO BOX 747, FALLS CHURCH, VA, 22040-0747, US

(21) Appl. No.: 10/110,402

(22) PCT Filed: Aug. 14, 2001
(86) PCT No.: PCT/DK01/00537

(30) Foreign Application Priority Data
Aug. 14, 2000 (DK) PA 2000 01208

(51) Int. Cl. H05K 9/00

(52) U.S. Cl. 174/35 R

(57) ABSTRACT

The invention relates to a shielding device to be fixedly arranged on a hand-held mobil radio transmission means (1), such as a mobile phone, and which protects a user against electromagnetic radiation from said radio transmission means (1) when said radio transmission means is used. The shielding device (10) comprises at least on substantially plane shielding member (12) of metal, where the metal is a nickel alloy, especially mu-metal. The shielding member (12) defines at least partially an acoustic resonance chamber (18) communicating with the air surrounding the shielding device through at least one sound channel (19). According to the invention, a shielding device (10) is obtained, which protects the user very efficiently against electromagnetic radiation transmitted by the radio transmission means (1) when it has been fixedly arranged on said radio transmission meams opposite the loudspeaker while it simultaneously allows sound from the loudspeaker to pass without causing a noticeably deterioration of the sound quality. The invention relates furthermore to a hand-held mobile radio transmission means (1), such as a mobile phone, and which has been provided with a shielding device (10).

### TECHNICAL FIELD

The invention relates to a shielding device to be fixedly arranged on a hand-held mobile radio transmission means, such as a mobile phone, and which protects a user against electromagnetic radiation from said radio transmission means when said radio transmission means is used, and where said shielding device comprises at least one substantially plane shielding member made of metal.

### BACKGROUND ART

The expression “radio transmission means” is here to be construed as a means used for communication by transmitting electromagnetic signals through the air. A radio transmission means is typically adapted to both receive and transmit electromagnetic signals, and thus it allows a communication both to and from said means. A hand-held mobile radio transmission means, such as a mobile phone, is adapted to transmit and receive the electromagnetic signals through the air by means of an antenna built into the radio transmission means. Typically, the antenna extends from the surface of the mobile terminal, but it can also be arranged inside the cover or the handset of the radio transmission means in order to make the mobile terminal rather compact. When the terminal is used, the user can move freely while having for instance a phone conversation. While the user is on the phone, the electromagnetic signals are transmitted and received by the mobile terminal adjacent the user, which may present a health risk to the user.

The entire transmission path between one radio transmission means and another radio transmission means is not necessarily through the air. It is for instance known that a radio transmission means can be part of a system including base stations or the like stations. Thus the radio transmission means can for instance transmit an electromagnetic signal through the air to a geographically nearby base station, which then handles the further transmission of the signal for instance through a fixed network of copper and/or optical cables cables or in another known way. In this manner the signal is for instance transmitted to a base station adjacent a receiving radio transmission means, which subsequently receives said signal in form of an electromagnetic signal through the air. As an alternative, the signal can be transmitted mobile-to-land or the like through the fixed network. In both cases the signal is thus only partially transmitted through the air. It should be noted that many different embodiments of radio transmission means are available, but they all share the common feature that they can transmit and/or receive data in form of electromagnetic signals through the air.

Below this type of means is referred to as hand-held mobile radio transmission means or mobile terminals, and they are usually in form of an assembled unit also comprising inter alia a loudspeaker and a microphone in addition to the above-mentioned antenna. The loudspeaker and the microphone allow a user to receive and transmit speach signals. Thus a mobile terminal is usually shaped such that it is possible for a user to use said terminal directly, i.e without necessitating a connection of additional equipment. The user can hold the mobile terminal towards his or her head in such a manner that the loudspeaker opposes his or her ear and the microphone is held adjacent his or her mouth. However, such a procedure implies that to a high degree the user is subjected to the electromagnetic field, said electromagnetic field applying around the mobile terminal. The electromagnetic field applies around the antenna of the mobile terminal and is caused by the electromagnetic radiation transmitted from the interior of the cabinet or the casing of said terminal. The electromagnetic radiation transmitted from the interior of the cabinet of the mobile terminal is inter alia caused by the fact that the electromagnetic signal transmitted by the antenna is generated by a transmitter unit placed inside said cabinet. In addition, the electromagnetic radiation is also caused by a portion of said antenna usually being placed inside said cabinet. It should be noted that many radio transmission means suffer from a relatively strong electromagnetic field in the portion of the cabinet housing the loudspeaker because said loudspeaker is often placed adjacent the built-in antenna.

As a mobile terminal is usually rather compact, the user is in particular exposed to an electromagnetic field around his or her head when he or she holds the terminal to his or her ear. Therefore, it is desired to provide a shielding which ensures that the head of the user is only subjected to a reduced quantity of electromagnetic radiation.

The latter presents a well-known problem, and various solutions have been developed. Thus it is known to use various types of shielding devices which can shield against the electromagnetic radiation, for instance by providing the antenna of the mobile terminal and the mobile terminal per se with shielding devices arranged between the mobile terminal and the user. In this connection it is known to form the shielding unit as a plate made of metal.

However, the latter solution is encumbered with the problem that as the shielding device shields both against the electromagnetic radiation and against the sound transmitted from the loudspeaker, said shielding device cannot be mounted directly opposite the loudspeaker in the mobile terminal. Therefore a shielding device shielding against the electromagnetic radiation is necessary, but where said shielding device simultaneously allows passage of sound from the loudspeaker inside the mobile terminal to the user of said mobile terminal.

A shielding device of the type mentioned in the preamble of claim 1 is known, said shielding device comprising a plate made of aluminium and being provided with a through opening. Once it has been fixedly mounted on a radio transmission means, this shielding device shields against electromagnetic radiation, and the opening allows sound to pass through said shielding device. However, such an opening has a negative effect on the degree of the shielding against the electromagnetic field, because the electromagnetic radiation can pass through said opening, and because an amplifying effect is generated when such an opening acts as a slit antenna.

### BRIEF DESCRIPTION OF THE INVENTION

The object of the invention is to provide a shielding device of the type described in claim 1, which ensures both an efficient protection of the user against electromagnetic radiation and allows passage of sound.

The shielding device according to the invention is characterised in that the metal is a nickel alloy, especially mu-metal, and that the shielding member at least partially defines an acoustic resonance chamber communicating with the air surrounding the shielding device through at least one sound channel. When the shielding device is fixedly arranged on the radio transmission means opposite the loudspeaker, said shielding device provides the user with the maximum shielding against electromagnetic radiation transmitted by the radio transmission means while said shielding device simultaneously allows sound from the loudspeaker to pass without causing a noticeable deterioration of the sound. The Ni-alloy, especially the mu-metal, provides an efficient shield against electromagnetic radiation while it simultaneously presents a good sound membrane in the acoustic resonance chamber.

As the sound channel extends substantially at least approximately parallel to a substantially plane wall in the shielding member as stated in claim 2, a particularly good protection against radiation is obtained at the same time as the sound is good. Such a particular extension direction of the sound channel involves a minimum of electromagnetic radiation from said sound channel, while it allows an easy passage of the sound.

According to an advantageous embodiment of the shielding device according to the invention, the side of the shielding member of nickel alloy facing the radio transmission means is coated with at least one layer of electromagnetically absorbing foam material, which at least partially forms defining walls for the resonance chamber as well as for the sound channel. In this manner the foam material absorbs a portion of the electromagnetic radiation and provides therefore an additional protection of the user against electromagnetic radiation.

According to a preferred embodiment of the shielding device according to the invention, the electromagnetically absorbing foam is polyurethane foam, which is referred to as PU foam below. The resilient properties of the PU foam have the effect that the shielding device adapts to possible irregularities on the outer surface of the radio transmission means. As a result, the shielding member closely abuts the radio transmission means after being mounted thereon. In addition, the PU foam turned out to possess good properties with respect to reflection of audio signals.

The electromagnetically shielding foam layer may according to the invention advantageously be secured to the shielding member of nickel alloy by means of an adhesive, such as a modified acrylic adhesive, whereas the opposite side of said foam layer is coated with a layer of auxiliary adhesive which in turn is covered by a detachable cover layer, such as silicone paper. As a result a particularly good securing of the shielding device to the radio transmission means is obtained, whereby said shielding device and consequently the shielding member are maintained in the mounted position despite repeated and rather strong effects from the outside, such as when the shielding device hits other physical articles or is subjected a high number of times to displacement forces by the rim of a pocket when it is put in said pocket. The detachable cover layer is advantageous in ensuring that the adhesive power of the auxiliary adhesive can be preserved despite long-termed storage prior to the mounting on a radio transmission means.

According to a further advantageous embodiment, the resonance chamber is of a substantially elliptical shape according to a sectional view in a direction parallel to the shielding member made of nickel alloy, preferably in a ratio b/a less than 0.5, especially less than 0.3, a representing the major axis of the ellipse and b representing the minor axis of said ellipse. As a result, the acoustic resonance chamber transmits the acoustic signals in an exceptionally good manner due to the elongated shape.

According to a preferred embodiment, the shielding member made of nickel alloy has been subjected to a surface treatment with an alkyd-based metal lacquer. As a result the surface can be touched by the user for instance in connection with the mounting of the device on a radio transmission means without said user coming into a direct contact with the nickel alloy.

According to an alternative embodiment, the plate-shaped shielding member of nickel alloy is elliptic and coated with a layer of plastics, such as resin, on the side facing the user. Such a shape implies that the shielding device adapts well to the ear shape of most users and can abut the ear of the user in a pleasant manner. In this manner it is ensured that the user automatically places the radio transmission means such that a good transmission of sound to said user is obtained. The plastics ensures that the user can place the radio transmission means in the latter manner without coming into direct contact with the nickel alloy. Resin is advantageous in providing a shield against electromagnetic radiation.

According to the invention, metal foil may be embedded in the plastic layer with the result that an additional shielding effect is obtained. Furthermore, it is possible to apply an advertising text or the like, said text advantageously being applied onto the metal foil.

The invention relates also to a hand-held mobile radio transmission means, such as a mobile phone, and which is provided with the shielding device according to one or more of the claims 1 to 9, and where the shielding device is fixedly mounted opposite a loudspeaker built into the radio transmission means. As a result, a particularly good shielding of the user is obtained against electromagnetic radiation at the same time as the sound can pass from the loudspeaker to the ear of the user in an improved manner.

According to a first advantageous embodiment of the radio tansmission means according to the invention, the shielding device is secured, preferably by way of sticking, to the outer side of the cabinet of said radio transmission means. In this manner the user can see directly that the radio transmission means has been provided with a shielding device and thus provides the desired shielding against electromagnetic radiation. An additional advantage is found in the fact that the shielding device can be mounted later on without necessitating an opening of the cabinet of the radio transmission means.

According to a second advantageous embodiment of the radio transmission means according to the invention, the shielding device is secured inside the cabinet of said radio transmission means, whereby said shielding device forms an integrated part of the radio transmission means. Thus the radio transmission means can be provided with a compact structure, and a particularly advantageous mounting is possible, such as a mounting directly on the loudspeaker. In the latter case the shielding device is well protected against strong mechanical effects, such as bumps and impacts which might destroy it.

According to a further advantageous embodiment according to the invention, the outer side of the cabinet of the radio transmission means represents a defining wall of the resonance chamber. The resulting structure involves a reduced amount of material, and accordingly a desired reduction of the weight of the radio transmission means is obtained as well.

### BRIEF DESCRIPTION OF THE DRAWINGS

The invention is explained in greater detail below with reference to the accompanying drawings, in which

FIG. 1A shows an embodiment of a hand-held mobile radio transmission means, on which the shielding device according to the invention can be mounted,

FIG. 1B is a longitudinal sectional view on a larger scale of the embodiment of FIG. 1A,

FIG. 2A illustrates the structure of an embodiment of a shielding device according to the invention, whereby the parts of the device have been pulled apart,

FIG. 2B illustrates an assembled shielding device according to the invention,

FIG. 3 is a longitudinal sectional view through the foam layer of a shielding device according to the invention,

FIG. 4A illustrates a first embodiment of a hand-held mobile radio transmission means according to the invention,

FIG. 4B illustrates a second embodiment of a hand-held mobile radio transmission means according to the invention,

FIG. 5A illustrates an alternative embodiment of a shielding device according to the invention, and

FIG. 5B illustrates a further alternative embodiment of a shielding device according to the invention.

### BEST MODE FOR CARRYING OUT THE INVENTION

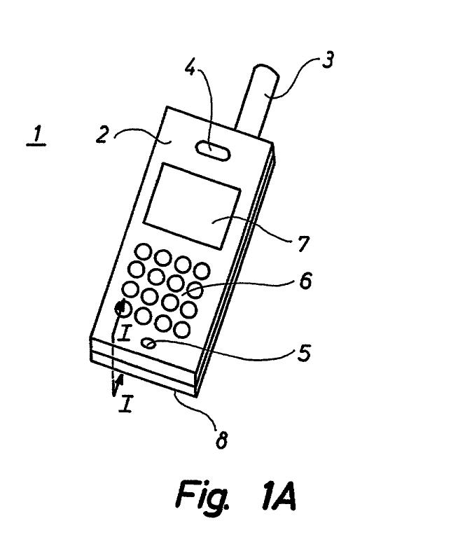

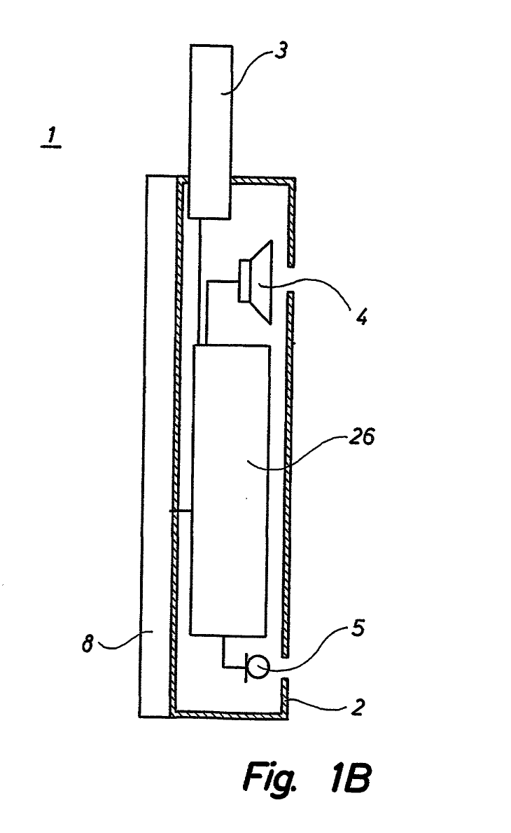

FIG. 1A illustrates a mobile phone as an example of a hand-held mobile radio transmission means or mobile terminal according to the prior art. A shielding device according to the invention can be mounted on this known radio transmission means and accordingly serve to shield against electromagnetic radiation from the mobile terminal. A mobile phone is used as example, but other mobile terminals are also possible as examples, such as a wireless phone connected to the fixed network or a walkie-talkie.

The mobile phone is designated the general reference numeral 1 and comprises a casing or a cabinet 2. The cabinet 2 houses an antenna 3, a loudspeaker 4 and a microphone 5. In the illustrated embodiment the antenna 3 extends from the cabinet 2 and is such that it can transmit and receive electromagnetic signals through the air and thus allow a transmission of data to and from the mobile phone 1. The loudspeaker 4 and the microphone 5 are arranged such that when a user moves the mobile phone 1 towards his or her head, said user can place the loudspeaker 1 at his or her ear and the microphone adjacent his or her mouth or at least sufficiently close to the mouth to ensure that the microphone 5 can catch a speach signal given by the user. In this manner it is possible for a user to use the mobile phone 1 directly, i.e. without necessitating a connection of additional equipment, such as for instance an external microphone and loudspeaker for receiving and transmitting audio signals, such as speach signals.

In addition, the illustrated mobile phone 1 also comprises a keyboard 6, a display 7 and a battery 8. The keyboard 6 can be used for various keyings, such as for keying a phone number in order to establish a contact with a mobile phone or a fixed network phone. The display 7 is used for presenting various data to the user, and the battery 8 is used as voltage source for the mobile phone.

FIG. 1B is a sectional view taken along the line I-I of FIG. 1A. As illustrated, the mobile phone 1 comprises also a control block 26 in addition to the cabinet 2, the antenna 3 and the battery 8. The control block 26 symbolizes various operating and control units forming part of a mobile phone, and only a single block has been shown in the Figure for the sake of clarity. Other details, such as the keyboard and the display of the mobile phone have been omitted from this Figure as well. The control block 26 is connected to the antenna 3 partly positioned inside the cabinet 2, and to a built-in loudspeaker 4 and a microphone 5. The loudspeaker 4 and the microphone 5 correspond to the loudspeaker and the microphone shown in FIG. 1A, said FIG. 1A only showing said loudspeaker and said microphone from the outer side of the cabinet and thus nothing but a sound opening to the loudspeaker 4 rearwardly arranged.

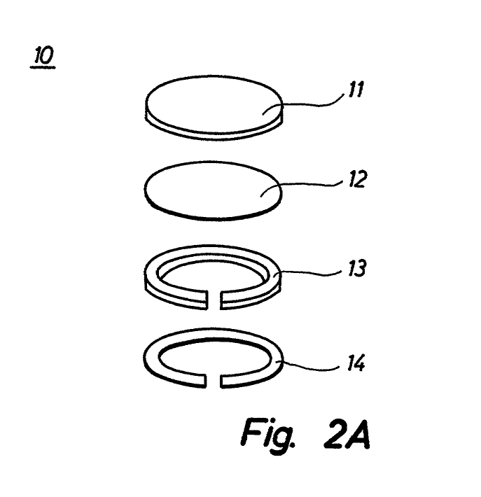

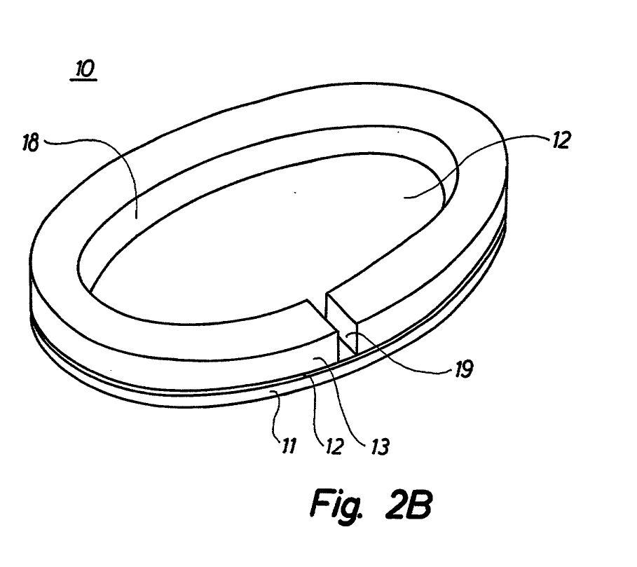

FIG. 2A shows an embodiment of the structure of a shielding device 10 according to the invention. As illustrated, the shielding device 10 is advantageously made of a number of layers, which have been pulled apart for the sake of clarity.

The shielding device 10 comprises a layer 12 of nickel alloy. This layer 12 is shaped as a substantially plane shielding member. The shielding device 10 is coated with an electromagnetic foam layer 13 on the side of the layer 12 facing a mobile terminal when mounted thereon, said foam layer being capable of absorbing electromagnetic radiation. This foam layer 13 is secured to the layer 12 of nickel alloy by means of an adhesive, such as a modified acrylic adhesive, whereas the opposite side of the foam layer 13 is coated with a layer of auxiliary adhesive, such as modified acrylic adhesive, with the result that the shielding device 10 can be reliably secured on a mobile terminal. Double faced adhesive tape can advantageously be used as adhesive between the layer 12 and the foam layer 13 as well as replace the above auxiliary adhesive. The auxiliary adhesive is covered by a detachable cover layer 14, such as silicone paper, silicone textile or another material not binding to the auxiliary adhesive. The two-part adhesive and the auxiliary adhesive do not appear from the Figure, but these adhesives are positioned between the individual layers as described above after the assembling of the illustrated layers into an assembled shielding device.

Together the layer 12 of nickel alloy and the foam layer 13 operate as a shield against electromagnetic radiation, and when they have been mounted on a mobile terminal they protect a user against such a radiation. The layer or the plate 12 can for instance be made of mu-metal, which turned out to have an exceptionally good shielding effect. Mu-metal is characterised by possessing a particularly high relative permeability, such as in the range 30,000 to 50,000. The foam layer 13 is a layer of foamed plastics, such as polyurethane (PU), polyethylene or polyvenyl chloride, and in a preferred embodiment it is made of polyurethane, as PU foam turned out to be able to absorb electromagnetic radiation. In addition, both the metal layer 12 and the foam layer 13 of PU foam turned out to possess good reflecting properties relative to audio signals, which is very advantageous in connection with the shielding device 10 according to the invention, cf. the more detailed explanation below.

As illustrated in FIG. 2A, the illustrated shielding device 10 can also be provided with a contact layer 11 on the side of the layer 12 facing a user. The contact layer 11 is the layer contacted by the user when he or she touches the loose shielding device. Care should be taken that the contact layer 11 covers the layer 12 completely, and it must at least cover the portions of the layer 12 optionally being touched by a user. According to a preferred embodiment, this contact layer 11 is made of plastics, such as resin, i.e. a resin-based material produced either naturally or artificially. The resin 11 protects the user well both against coming into direct contact with the layer 12 and against the electromagnetic radiation However, it should be mentioned that the contact layer 11 can be made of other materials beyond resin, such as for instance rubber, metal, carbon fibre or even wood. The contact layer 11 of plastics can be secured to the layer 12 by means of an adhesive, such as a modified acrylic adhesive. A metal foil can be embedded in the plastic layer 11, said metal foil also shielding against electromagnetic radiation. As an alternative, the contact layer 11 can be provided by way of a surface treatment of the layer 12 of nickel alloy or be a separately applied layer. The latter layer can advantageously for instance be applied onto the side facing the mobile terminal 1. In the illustrated embodiment, the surface treatment is carried out by an alkyd-based metal lacquer being applied onto the layer 12.

FIG. 2B illustrates a shielding device 10 also shown in FIG. 2A, where the individual layers have been assembled. As illustrated, the foam layer 13 forms part of the defining walls of an acoustic resonance chamber 18 in this embodiment. The resonance chamber 18 is defined by the layer 12 of nickel alloy, the foam layer 13 and the exterior of a mobile terminal 1, on which the device is to be mounted. When the resonance chamber is substantially elliptical, said resonance chamber 18 is also defined by the plate 12 in a direction towards the user of the outer surface of the mobile terminal, in the direction towards the mobile terminal and by the foam material in the remaining directions. The foam layer 13 forms also defining walls for a sound channel 19 connecting the resonance chamber 18 with the surrounding air. As a result, the sound from the resonance chamber 18 can propagate through the sound channel 19 to the surroundings. In the illustrated embodiment, the sound channel 19 extends parallel to or approximately parallel to the plate 12 of nickel alloy.

As mentioned above, the foam layer 13 is PU foam in the illustrated shielding device. This material has been selected due to its good absorbing properties towards electromagnetic radiation. In addition, PU foam turned out to possess a number of additional advantages, such as for instance a low density and a good resilience. The resilience implies that the device 10 can yield to physical effects to a predetermined degree. Therefore, the PU foam and the adhesive result in a very strong retaining of the shielding device 10 relative to the radio transmission means.

It should be noted that the plate 12 can advantageously present a thickness of 0.5 mm or less because such a small thickness relative to the other dimensions of the plate implies that said plate automatically can deform easily in a resilient manner with the result that said plate 12 operates as a good sound membrane.

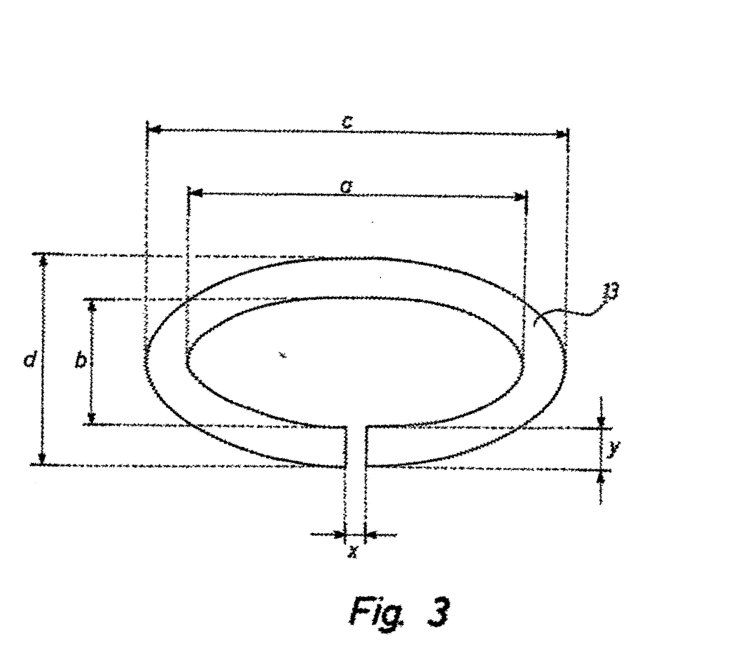

FIG. 3 is a cross sectional view of the shielding device 10 of FIG. 2A. The sectional view extends through the foam layer 13. It appears that according to this sectional view, the resonance chamber 18 is substantially elliptic, and below this shape is referred to as the inner ellipse. As illustrated in the Figure, the foam layer 13 can also present an outer elliptic shape or be at least approximately elliptic, and below this shape is referred to as the outer ellipse. In the illustrated embodiment, the inner and the outer ellipse share a common centre. When the outer ellipse presents a major axis c of for instance 28.0 mm and a minor axis d of for instance 18.0 mm, the inner ellipse can present a major axis a of for instance 20.0 mm and a minor axis b of for instance 10.0 mm. As illustrated in the Figure, the sound channel 19 can be of a length y of approximately 4.0 mm and a width x of approximately 2.0 mm. The height of the sound channel 19 corresponds to the height of the resonance chamber 18, and the height of said sound channel 19 is determined by the thickness of the foam layer 13, which in the illustrated embodiment is 0.8 mm. In the illustrated embodiment, the ratio of the minor axis b to the major axis a of the inner ellipse is b/a equal to 0.5, which turned out to ensure good acoustic results for the resultantly defined acoustic resonance chamber 18. The ratio b/a should preferably be 0.5 or less because an elongated shape of the acoustic resonance chamber results in a good transmission of acoustic signals through the chamber 18. Particularly good conditions can be obtained by means of a ratio of 0.3 or less. In the illustrated embodiment, the ratio of the width of the sound channel to the length thereof and the ratio of the height of said sound channel to the length thereof is equal to 0.5 and 0.2, respectively, which turned out to ensure a good transmission of the sound. The relatively small distance between the layer 12 and the outer surface of the mobile terminal renders it possible to place the shielding device at the location where the distance from the sound opening in the cabinet of the mobile terminal is significantly larger than the distance between the outer surface of the terminal and the layer 12, said shielding device being mounted on said outer surface of the mobile terminal relative to the size of the inner ellipse. As a result a particularly good shielding against electromagnetic radiation is obtained.

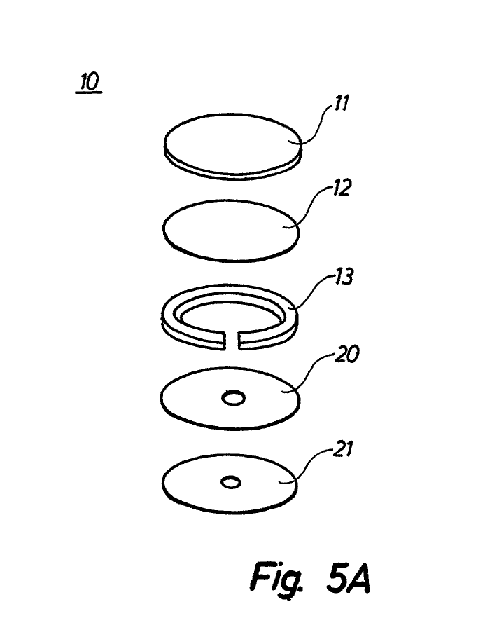

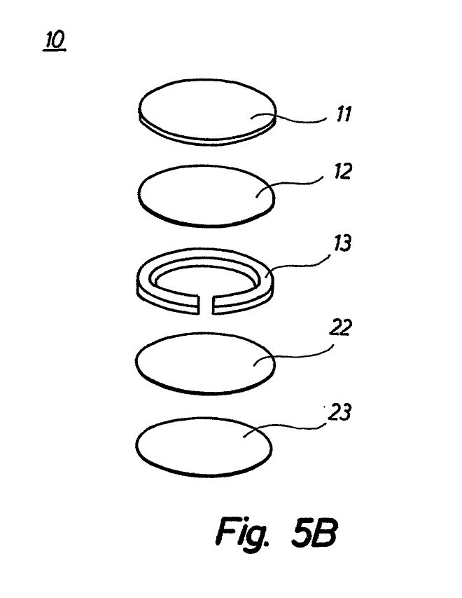

As shown in FIG. 5A, the resonance chamber 18 can be covered by a cover layer 20 on the side facing the mobile phone 1. Like in FIG. 2A, the parts of the device have been pulled apart in FIG. 5A. The illustrated embodiment ensures that dust and the like particles do not accumulate in the resonance chamber 18 prior to the mounting because said chamber 18 is covered. A layer of adhesive and a detachable cover layer 21 can be applied onto the cover layer 20 with the result that an exceptionally good securing to the mobile phone is obtained upon the mounting, if requested. As illustrated, the cover layer 20 can be provided with a sound-penetrable opening. This sound-penetrable opening can be placed opposite the loudspeaker 4 of the mobile phone and be secured to the foam layer 13, such as by means of a double faced adhesive of the type mentioned above. FIG. 5B illustrates an alternative embodiment of the shielding device 10 according to the invention. This embodiment comprises a cover layer 22 of a sound-penetrable material and a detachable cover layer 23. It should be noted that portions of the resonance chamber 18 and/or the sound channel 19 can be filled correspondingly with a sound-penetrable material not shown. However, it should be underlined that the preferred embodiment comprises a hollow resonance chamber allowing the sound to propagate through the air therein. In addition it should be noted that the detachable cover layer 23 can also operate as cover layer for the resonance chamber 18 while the device is stored provided it is shaped for instance like the cover layer 22. As a result the cover layer 22 can be omitted, if desired.

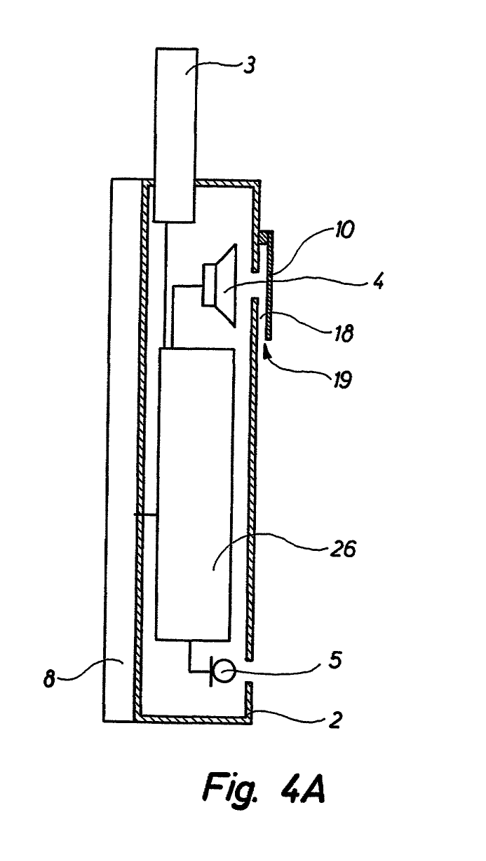

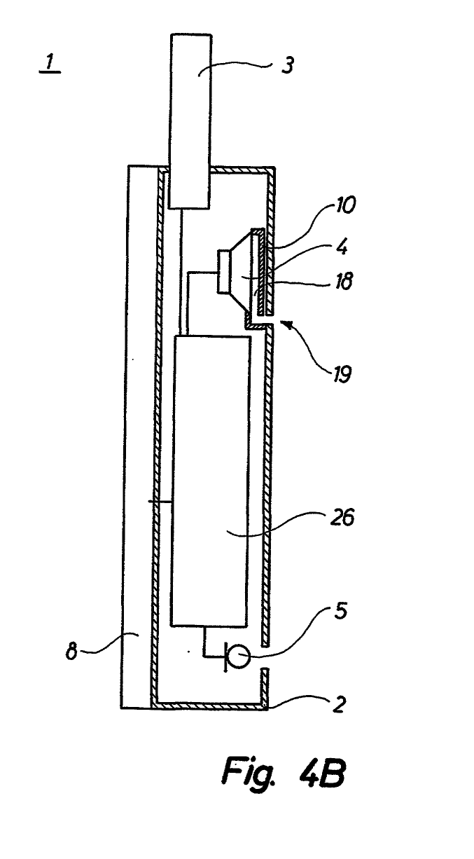

FIG. 4A illustrates a first embodiment of a radio transmission means according to the invention, where the shielding device 10 is secured to the outer side of the cabinet 2 of the radio transmission means 1. As a result, a resonance chamber 18 and a sound channel 19 are formed between the outer side of the cabinet 2 and the shielding device 12 in such a manner that sound can be transmitted from the loudspeaker 4 to a user through the resonance chamber 18 and the sound channel 19.

FIG. 4B is a cross sectional view through an alternative embodiment of a radio transmission means according to the invention, where the shielding device 10 is secured inside the cabinet 2 of said radio transmission means 1. Here the shielding device 10 is secured to the loudspeaker 4 which ensures particularly good conditions for the transmission of audio signals from said loudspeaker. In addition, a shielding against the electromagnetic radiations from the radio transmission means 1 is obtained. Although preferred embodiments of the present invention have been described and illustrated, the protection is not limited thereto, but covers also other embodiments, cf. the following claims. The placing and the number of sound channels from the resonance chamber to the air surrounding the shielding device can for instance vary, such as by two, three or four sound channels symmetrically arranged about the major axis and the minor axis of the outer ellipse. The size and the shape of the resonance chamber and of the sound channel or the sound channels can also vary from one embodiment to the next embodiment in such a manner that said parts form a large or a small part of the shielding device. The shielding device can also comprise a low amount of layers, such as two layers, viz. one layer of nickel alloy and one layer of foam, or only one layer of nickel alloy shaped in such a manner that said layer per se defines, viz. houses, the acoustic resonance chamber. The shielding device can optionally comprise even more layers in addition to the layers in the illustrated embodiment. The shielding device can for instance comprise more shielding metal layers where at least one metal layer is made of a nickel alloy, more foam layers and/or more contact layers. According to another embodiment, the layer 12 can be vapour deposited on the foam layer 13. The resonance chamber can also be of other shapes beyond the elliptic, such as for instance circular or square. Finally, it should be mentioned that the shielding device can also advantageously be used for protecting a user against the electromagnetic field applying around a microphone of a radio transmission means, while said device simultaneously allows sound to pass to said microphone.

1. A shielding device to be fixedly arranged on a hand-held mobile radio transmission means (1), such as a mobile phone, and which protects a user against electromagnetic radiation from said radio transmission means (1) when said radio transmission means is used, and where said shielding device (10) comprises at least one substantially plane shielding member (12) made of metal, characterised in that the metal is a nickel alloy, especially mu-metal, and that the shielding member (12) at least partially defines an acoustic resonance chamber (18) communicating with the air surrounding the shielding device through at least one sound channel (19).

2. A shielding device as claimed in claim 1, characterised in that the sound channel (19) extends substantially at least approximately parallel to a substantially plane wall in the shielding member (12).

3. A shielding device as claimed in claim 1 or 2, characterised in that the side of the shielding member (12) of nickel alloy facing the radio transmission means (1) is coated with at least one layer of electromagnetically absorbing foam material (13), which at least partially forms defining walls for the resonance chamber (18) as well as for the sound channel (19).

4. A shielding device as claimed in claim 3, characterised in that the electromagnetically absorbing foam is polyurethane foam.

5. A shielding devices claimed in claim 3 or 4, characterised in that the electromagnetically shielding foam layer (13) is secured to the shielding member (12) of nickel alloy by means of an adhesive, such as a modified acrylic adhesive, whereas the opposite side of said foam layer (13) is coated with a layer of auxiliary adhesive which in turn is covered by a detachable cover layer (14), such as silicone paper.

6. A shielding device as claimed in one or more of the preceding claims 1 to 5, characterised in that the resonance chamber (18) is of a substantially elliptical shape according to a sectional view in a direction parallel to the shielding member (12) made of nickel alloy, preferably in a ratio b/a less than 0.5, especially less than 0.3, a representing the major axis of the ellipse and b representing the minor axis of said ellipse.

7. A shielding device s claimed in one or more of the preceding claims, characterised in that the shielding member (12) of nickel has been subjected to a surface treatment with an alkyd-based metal lacquer.

8. A shielding device as claimed in one or more of the preceding claims, characterised in that the plate-shaped shielding member (12) of nickel alloy is elliptic and coated with a layer of plastics (11), such as resin, on the side facing the user.

9. A shielding device as claimed in claim 8, characterised in that a metal foil is embedded in the plastic layer (11).

10. A hand-held mobile radio transmission means (1), such as a mobile phone, and which is provided with the shielding device (10) as claimed in one or more of the claims 1 to 9, and where said shielding device (10) is fixedly mounted opposite a loudspeaker (4) built into the radio transmission means.

11. A radio transmission means as claimed in claim 10, characterised in that the shielding device (10) is secured, preferably by way of sticking, to the outer side of the cabinet (2) of said radio transmission means.

12. A radio transmission means as claimed in claim 10, characterised in that the shielding device (10) is secured inside the cabinet (2) of the radio transmission means.

13. A radio transmission means as claimed in claim 11, characterised in that the outer side of the cabinet (2) of the radio transmission means represents a defining wall of the resonance chamber (18).
